(19) United States
(12) Patent Application Publication
(10) Pub. No.: US 2024/0337922 A1
(43) Pub. Date: Oct. 10, 2024

(54) EXTREME ULTRAVIOLET PELLICLE STORAGE AND METHOD OF PRESERVING EXTREME ULTRAVIOLET PELLICLE PROPERTIES THEREOF

(71) Applicant: LINTEC OF AMERICA, INC., Plano, TX (US)

(72) Inventors: Marcio D. LIMA, Richardson, TX (US); Sergey LI, McKinney, TX (US); Hooman RAHMANI, Plano, TX (US)

(73) Assignee: LINTEC OF AMERICA, INC., Plano, TX (US)

(21) Appl. No.: 18/618,374

(22) Filed: Mar. 27, 2024

Related U.S. Application Data
(60) Provisional application No. 63/457,890, filed on Apr. 7, 2023.

(51) Int. Cl. G03F 1/66; B65D 81/20; B65D 85/38; G03F 1/64

(52) U.S. Cl. CPC G03F 1/66; B65D 81/2007; B65D 81/2069; B65D 85/38; G03F 1/64

(57) ABSTRACT

A method of storing extreme ultraviolet (EUV) pellicles or pellicle film is disclosed. The method includes selecting a material, such as stainless steel or glass material, for the construction of the storage or transportation containers. Vacuum-sealed or inert-gas-filled containers are further preferred. The material maintains one or more properties of extreme ultraviolet (EUV) lithography pellicle, the one or more properties being selected from EUV transmission rate, EUV transmission variation, EUV scattering, EUV pellicle film deflection, EUV pellicle film tensile strength, or a combination thereof.

### TECHNICAL FIELD

This disclosure generally relates to the storage of ultra-thin films and ultra-thin film devices used in semiconductor microchip fabrications, and more particularly, storage container material to store and transport ultra-thin, ultra-low density, nanostructured free-standing pellicle films properly to avoid or reduce undesired effects on the ultra-thin films and/or ultra-thin film devices because of outgassing from container material.

### BACKGROUND

A pellicle is a protective device that covers a photomask and is used in semiconductor microchip fabrication. The photomask may refer to an opaque plate with holes or transparencies that allow light to shine through in a defined pattern. Such photomasks may be commonly used in photolithography and the production of integrated circuits. As a master template, the photomask is used to produce a pattern on a substrate, normally a thin slice of silicon known as a wafer in the case of semiconductor chip manufacturing.

Particle contamination is often a significant problem in semiconductor manufacturing. It becomes a more prominent issue in advanced photolithography of much high-resolution processes, affecting product yields as any nonnegligible particles may alter the printing patterns of logic circuits on the chips, which have no built-in redundancy.

A photomask is protected from particles by a pellicle, a thin transparent film stretched over a frame (also referred to as a pellicle border with a central opening) that is attached over the patterned side of the photomask. The pellicle is close to but far enough away from the mask so that moderate-to-small-sized particles that land on the pellicle will be too far out of focus to print. However, fall-on particles are still observed after a period of exposure usage with unknown particle sources, according to field reports in the semiconductor industry.

Recently, the microchip manufacturing industry realized that the pellicle might also protect the photomask from damage stemming from causes other than particles and contaminants.

Extreme ultraviolet (EUV) lithography is an advanced optical lithography technology using a range of EUV wavelengths, more specifically, about 13.5 nm wavelength. The EUV lithography enables semiconductor microchip manufacturers to pattern the most sophisticated features at 7 nm resolution and beyond, and place many more transistors without increasing the size of the required space. EUV photomasks work by reflecting light, which is achieved by using multiple alternating layers of molybdenum and silicon. When an EUV light source turns on, the EUV light hits the pellicle film first, passes through the pellicle film, and then bounces back from underneath the photomask, hitting the pellicle film once more before it continues its path to print a microchip. Some of the energy is absorbed during this process, and heat may be generated, absorbed, and accumulated as a result. The temperature of the pellicle may heat up to anywhere from 500° Celsius to 1000° Celsius or above.

While heat resistance is important, the pellicle must also be highly transparent for EUV transmission to ensure the passing through of the reflected light and light pattern from the photomask. This is one of the main reasons that EUV pellicles are generally very thin, which may be less than 200 nm, preferably less than 100 nm, or less than 40 nm in thickness.

In 2016, a polysilicon-based EUV pellicle was developed after decades of research and effort with only 78% EUV transmission on a simulated relatively low-power 175-watt EUV source. Due to greater transistor density demand, stringent requirements present further technical challenges to EUV pellicle developers for a higher transmission rate, lower transmission variation, higher temperature tolerance, and strong mechanical strength.

Attempts have been made to target a high light transmittance rate by deploying a high carbon nanotube content in a carbon nanotube sheet (e.g., as high as 99% by mass). Such attempts have resulted in a product that may also meet the mechanical strength and/or durability of the pellicle film requirements based on current industry standards. Further improvements include fulfilling more stringent standards, improving user experience, lowering production costs, and creating financial benefits. Accordingly, such carbon nanotube-based thin film has to provide a certain level of thickness to support its structural integrity. As a result, EUV transmission of such carbon nanotube-based thin films may require compromise when dealing with thicker films. Therefore, techniques beyond conventional technology and knowledge to accommodate both the transmission of EUV light and the thickness of the pellicle film have been sought and created to make further progress.

An attempt to produce ultra-thin, ultra-low density Carbon nanotube (CNT) pellicle film hit its milestone as published in WO 2021/090699. In this application, an ultra-thin film (about 3 nm) with a size as large as the current industry standards was achieved. However, such ultra-thin films, as thin as about 3 nm, present practical challenges since they are prone to damage, modification, or alternation during product packaging, shipping and handling, human and robotic maneuvers, and post-production storage.

However, CNTs are found to be sensitive to volatile organic compounds (VOCs) and may adsorb certain gaseous molecules and environmental pollutants, even in a minute quantity, which may ultimately alter CNT surfaces, and if exposed long enough, causing CNT property changes, especially for an ultra-thin CNT film. Such changes will inevitably affect light and EUV transmittance and scattering, which should be avoided.

Accordingly, a proper storage and transportation environment is critical for storing ultra-thin CNT pellicles or nanofiber pellicles to maintain pellicle film properties with little or no alteration to their high EUV transmission rate.

### SUMMARY

According to an aspect of the present disclosure, a nanostructure film is disclosed after being in a storage or transportation container for at least one day. The nanostructure film includes a plurality of nanofibers that are intersected randomly to form an interconnected network structure in a planar orientation, the intersected or interconnected network structure having a thickness ranging from a lower limit of 3 nm to 100 nm or up to an upper limit of 500 nm, and a light transmission rate from 50% and above to 95% and above when measured at 550 nm wavelength and an EUV transmission rate from 75% and above to 94% and above, up to 99%, in which the nanofiber structures may be pristine (i.e., the nanofiber structures do not expose to any treatment or surface modification after production) or undergo an annealing process, e.g., thermal annealing or laser annealing. The nanostructure film may be further coated with a substance selected from a metal, a metal oxide, its derivatives, or a combination thereof. The nanofibers may be carbon nanofibers, carbon nanotubes (CNTs), boron nitride nanotubes (BNNTs), or a combination thereof. The present disclosure further includes the EUV pellicle storage or transportation container comprising a non-outgassing or minimum outgassing material, including, but not limited to, stainless steel or glass. The CNT EUV pellicle films may include any combination of singled-walled, double-walled, and multi-walled carbon nanotubes (having 3 or more walls) and other types of carbon-based or non-carbon-based nanofibers. Such nanostructure films present and maintain a high EUV transmission rate and meet other EUV photolithography requirements and standards after being manufactured, optionally coated and/or annealed, and stored on a shelf for at least one day, preferably for at least one week and/or at least one month, in a storage container or transportation container. The disclosed nanostructure films further preserve their high EUV transmission rate substantially equal to the value measured upon completion of their production.

According to an aspect of the present disclosure, a storage device is disclosed. The storage device includes a material, which maintains one or more properties of an extreme ultraviolet (EUV) lithography pellicle. The one or more properties is selected from EUV transmission rate, EUV transmission variation, EUV scattering, EUV pellicle film deflection, EUV pellicle film tensile strength, or a combination thereof.

According to a further aspect of the present disclosure, some materials may outgas and alter the one or more properties of the EUV lithography pellicle, while other materials may outgas without altering the one or more properties of the EUV lithography pellicles. A material for the EUV pellicle storage container should maintain the one or more properties of the EUV lithography pellicles if outgassing. A material should be screened or treated for maintaining the one or more properties of the EUV lithography pellicle if the material outgases.

According to one aspect of the present disclosure, the material for an EUV pellicle storage container includes stainless steel.

According to another aspect of the present disclosure, the material for an EUV pellicle storage container includes glass.

According to a further aspect of the present disclosure, the material for an EUV pellicle storage container includes glass-ceramic or quartz.

According to yet another aspect of the present disclosure, material for an EUV pellicle storage container includes borosilicate glass.

According to a further aspect of the present disclosure, the storage device is vacuum-sealed.

According to a further aspect of the present disclosure, the storage device is filled with an inert gas.

According to a further aspect of the present disclosure, the material is pre-purged with an inert gas. The pre-purged material may outgas the inert gas under a vacuum pressure.

According to an aspect of the present disclosure, a method of storing an EUV lithography pellicle is disclosed. The method includes preparing an EUV lithography pellicle; and placing the EUV lithography pellicle in a container. The container comprises at least a material, and the material maintains EUV lithography pellicle one or more properties selected from EUV transmission rate, EUV transmission variation, EUV scattering, deflection of EUV lithography pellicle film, tensile strength of EUV lithography pellicle film, or a combination thereof.

According to a further aspect of the present disclosure, the material is selected from stainless steel, glass, borosilicate glass, glass-ceramic, or quartz.

According to a further aspect of the present disclosure, the method further includes maintaining a vacuum pressure within the container.

According to a further aspect of the present disclosure, the method further includes filling the container with an inert gas.

According to a further aspect of the present disclosure, the method further includes purging the material included in the container with an inert gas.

According to a further aspect of the present disclosure, the material selected for an EUV pellicle storage container releases no gaseous molecules, no volatile organic chemicals, or no vapor from inside of the material to their surrounding environment (i.e., does not outgas).

### BRIEF DESCRIPTION OF THE DRAWINGS

The present disclosure is further described in the detailed description which follows, in reference to the noted plurality of drawings, by way of non-limiting examples of preferred embodiments of the present disclosure, in which like characters represent like elements throughout the several views of the drawings.

FIG. 1 illustrates a filtration method for forming a pellicle film followed by an optional annealing step at an elevated temperature in accordance with an exemplary embodiment.

FIG. 2 illustrates a scanning electron microscope (SEM) image of a nanostructure of a double-wall CNT (DWCNT)-dominant film in accordance with an exemplary embodiment.

FIG. 3 illustrates Fourier-transform infrared (FTIR) spectra of CNT films before and after annealing treatments and annealed CNT film stored for 24 hours in a plastic container after annealing in accordance with an exemplary embodiment.

FIG. 4 illustrates FTIR spectra of CNT films before and after annealing treatments and annealed CNT film stored for 24 hours in a glass container in accordance with an exemplary embodiment.

FIG. 5 illustrates FTIR spectra of annealed CNT films immediately after annealing and one day, 27 days, and 35 days after annealing and stored in a glass container in accordance with an exemplary embodiment.

### DETAILED DESCRIPTION

Through one or more of its various aspects, embodiments and/or specific features, sub-components, or processes of the present disclosure are intended to bring out one or more of the advantages as specifically described above and noted below.

A pellicle may refer to a thin transparent film that protects a photomask during semiconductor microchip production. The pellicle contemplates a protective device with 1) a border or a frame and 2) a central opening or aperture. Both border and aperture are covered by a continuous thin film on the top of at least a portion of the border and a portion of the aperture, preferably the entire aperture and a portion of the border proximate to the aperture or the entire border. The center portion of such a thin film extending the aperture is free-standing. The pellicle may act as a dust cover that prevents particles and contaminants from falling onto the photomask during production. However, the pellicle must be sufficiently transparent to allow the light transmission necessary to perform lithography. Higher light transmission is desired for more effective lithography. For most EUV lithography applications, a 80% EUV transmission rate from a pellicle may be sufficient. For high-resolution EUV lithography at 5 nm or below, a high-energy EUV scanner (>250 Watts), or a high numeric aperture EUV lithography scanner (0.25), an EUV transmission rate above 92%, above 94%, or 96% up to 99% is desired.

Further, pellicles for EUV lithography require a large (e.g., greater than 110×140 mm) free-standing, thin-film material with extreme and unique properties. Besides high transparency to EUV radiation, any unexpected EUV transmission variation (also referred to as EUV transmission evenness) of a single pellicle or overall EUV transmission reduction may cause detrimental effects during manufacturing processes, leading to faulty printing results, lower production yields, etc. And EUV pellicle films may be required to be resistant to temperatures above 400° C. and mechanically robust to survive handling, shipping, and pumping down and venting operations during the photolithographic process. Pellicle film's gas permeability but with a capacity to retain micrometer-sized particles is also desired. Given the number of high-level properties required, effective EUV pellicles have been conventionally difficult to produce and require unconventional care post-production.

### Carbon Nanotubes and Carbon Nanotube Films

Carbon nanotubes (CNTs) or carbon nanofibers, as often referred to herein, are long tubes with small diameters typically measured in nanometers. They have a high aspect ratio of length vs. diameter in a range generally preferred above about 100:1, which may be above about 1000:1. Another preferred aspect ratio may be at least approximately 10,000:1. CNTs are made up of one or more graphene sheets rolled up into a concentric structure. Each graphene sheet is regarded as a wall of a CNT. A single-wall CNT (SWCNT) is made of a single graphene sheet. A double-wall CNT (DWCNT) is made of two graphene sheets. Lastly, a multiwall CNT (MWCNT) has 3 or more graphene sheets. Other types of CNTs may include, but are not limited to, coaxial nanotubes (either homogenous or heterogenous-referring to same or different inner wall(s) and exterior wall(s) of coaxial nanotubes), conical carbon nanotubes, and closed carbon nanotubes. Other carbon allotropes, including metallic or semiconductive carbon nanotubes, may also form sheets with excellent properties for pellicle films. For CNTs, they may exist substantially pure in one type or often in combination with other types with respect to the number of CNT walls. The CNTs may also exist individually, separated from others, or form bundles. A bundle may include the same type or different types of CNTs, such as SWCNT with DWCNT, SWCNT with MWCNT (3 or more walls), etc. Within a bundle, individual CNTs may have different lengths and diameters. Each bundle, having two or more CNTs, may be aligned in parallel, at least for a portion of their entire lengths. For simplicity and convenience, CNTs in this application may refer to different types of CNTs, for example, different numbers of walls, and include CNTs existing individually or in bundles.

As used herein, nanofiber may exemplarily refer to a fiber having a diameter less than 1 μm. Nanofiber and nanotube are used interchangeably and may encompass SWCNTs, DWCNTs, MWCNTs, and other carbon allotropes in which carbon atoms are linked together to form a cylindrical structure.

An individual CNT may be intersected with one or more other CNTs. Together, many CNTs could form a mesh-like nanostructure film. One exemplary embodiment may include a free-standing nanostructure thin film, of which an area of the thin film has no supporting material or substrate on either side of the thin film. While such formation is possible, it may not be guaranteed in every trial, especially for making an ultra-thin film with high transparency and other properties qualified for EUV lithography pellicles.

Further, among several possible methods to fabricate free-standing films, a filtration-based approach was utilized to produce films from small-size films to sufficiently large films with uniform film thickness for EUV lithography. Films having a uniform thickness correlate to even light transmission. This filtration-based method allows for the quick manufacturing of films not only of CNTs but also other high aspect ratio nanoparticles and nanofibers, such as boron nitride nanotubes (BNNT) or silver nanowires (AgNW). Since this approach separates the nanotubes or nanoparticle syntheses and the film manufacturing processes, a variety of types of nanofibers produced by virtually any method may be used. Different types of nanotubes (SWCNT, DWCNT, MWCNT, or carbon allotropes) may be mixed in any desired ratio. As filtration can be a self-leveling process in the sense that non-uniformities of film thickness during the filtration process are self-corrected by the variations of local permeability and, therefore, a highly desirable film formation process, it is also a promising candidate for the production of highly uniform films.

### Annealing Treatment

Annealing refers to a process of applying a heat treatment to a material to alter the given material's physical and sometimes chemical properties to increase its ductility and reduce its hardness. Annealing starts with a heating source, administrates the heating energy onto a material to raise the temperature of such material from its ambient temperature to a predetermined elevated temperature, holds the desired temperature for a preselected treatment duration, and then lets the material cool off.

The heating performed for annealing may be electrical heating, in which an electric current, voltage, and/or electrical energy are passed through a material by directly contacting the material.

Alternatively, heating performed for annealing may be convection heating. An exemplary convection heating flows a heated gas over the surface and/or sometimes the material interior passage and raises the target's temperature.

Another heating performed for annealing may be radiant heating, in which an electromagnetic wave is directed toward a targeted material. A light source within a visible spectrum, including a laser, can heat a target material by delivering radiation directly upon a target or target surface. The photons of the light may bounce, re-radiate, or scatter, which may cause uneven heating due to any topographical differences, features, and/or unevenness of a given area of the material. An environment carrying out such treatment and interfering with a light pathway toward a target may cause uneven annealing results. This unevenness brought by a direct light treatment becomes more prominent for an area receiving repetitive irradiation vs. irradiation avoidance areas if the entire material surface is not irradiated simultaneously. Furthermore, laser treatments may burn, ablate, or sublimate surface material. Even a trace amount of such “lifted” material generated by laser treatment, which could be in the form of small molecules or elements, may be reabsorbed or redeposited to an untreated or sometimes treated surface, thus, creating new unevenness or exacerbating existing non-uniformity.

However, aspects of the present disclosure are not limited thereto, such that different heating operations/methods may be performed or a combination of heating operations may be performed.

Annealing may be thermal annealing, which may use an electromagnetic wave within a non-visible light spectrum, including but not limited to infrared (e.g., near, mid, and/or far infrared). Such electromagnetic wavelength may have a range selected from between about 10 nm to about 1 mm. A preferred range may also be selected from between about 400 nm to about 700 nm or between about 700 nm to about 1 mm. Yet another preferred wavelength may be between about 5 μm to about 20 μm. This heating method transfers energy to a target material while the thermal energy dissipates into other microscopic motions within a material. In other words, thermal annealing distributes its energy power and heats a target material to raise the temperature uniformly. Thermal annealing covers the entire object regardless of the direction of the incoming energy source. Ceramic heating by a ceramic heating tube with sufficient inner space for the reception of full-size pellicles is one of many choices to implement invisible light spectrum-based thermal heating. The heating element may be made of silicon carbide and molybdenum disilicide. Without wishing to be bound by scientific theory, it is believed other heating elements and heating devices are also applicable.

In a heating tube, one or multiple heating sources or heating elements are arranged in a circular array from a cross-section view or tubular arrangement with respect to the overall heating device shape. Electromagnetic waves from such a heating source will distribute radiation uniformly within the tubular chamber. With a proper electromagnetic wave spectrum and emitting sources, such annealing provides and ensures uniform radiation arriving at a CNT pellicle and covering the entire pellicle area at any given time during the process, thus, yielding the least or lower EUT transmission variation compared to non-whole film field annealing.

The annealing treatment in the exemplary embodiments includes but is not limited to, the above-mentioned heating methods.

The common annealing temperature may be any temperature above an ambient temperature. It may be 50° C. and above, 100° C. and above, 300° C. and above, 500° C. and above, 600° C. and above, 650° C. and above, 700° C. and above, 800° C. and above, 900° C. and above, or 1,000° C. and above. It may also be 3,000° C. or less, 2,500° C. or less, 2,000° C. or less, 1,800° C. or less, 1,700° C. or less, 1,600° C. or less, 1,500° C. or less, or 1,400° C. or less. A heating temperature may be within a range of any two aforementioned temperatures.

Selecting an annealing temperature may require further consideration of other factors, such as a suitable temperature range depending on the material properties of pellicle borders, such as their thermal expansion property. A low thermal expansion property is preferred (e.g., quartz) for the pellicle border.

The annealing temperature may ramp up at a fixed or a variable speed, depending on the heating devices/methods utilized and heating devices' heating capabilities. A common and practical temperature climbing speed may be about 20° C./min. A preferred heating regimen heats CNT pellicles swiftly to avoid or limit potential CNT oxidation due to possible chemical contaminants adhered onto an annealing chamber or mixed in with a flow-through gas. A heating regimen may also have a balance with pellicle borders' physical and sometimes chemical properties and their thermal expansion to avoid cracking of the pellicle borders.

Post-annealing cooling may allow the elevated temperature to return to ambient conditions naturally. Alternatively, it may utilize flowing a cooling gas, an ambient temperature gas, or a gas with descending temperature over a period of time to cool off the annealing chamber. An inert gas is preferred hereof.

Annealing treatment may occur in a vacuum (e.g., vacuum annealing), partial vacuum, or at atmospheric pressure. Additionally, it may occur in the presence of an inert gas or non-inert gas, such as a hydrocarbon gas.

Exemplary inert gases include but are not limited to, argon, helium, neon, krypton, xenon, and radon. Exemplary hydrocarbon gases include but are not limited to methane, ethane, propane, butanes, pentanes, hexane, and heptane.

Gas may flow through the annealing chamber at a constant or variable flow rate. Two or more gas types as a gas mixture may flow through the annealing chamber at a constant or variable flow rate. Further, the two or more gas types may flow continuously or intermittently. A gas or gas mixture may be preheated before being injected into an annealing chamber for convection heating and/or be actively heated while inside an annealing chamber. A gas or gas mixture may be purposely selected and injected during annealing. For example, applying a hydrocarbon gas has been previously reported to repair structural defects of nanofibers and nanoparticle formation on the pellicle film surfaces. Due to the nature of working with ultra-thin, ultra-low-density film, a constant gas flow or a gas with the least variable flow speed may be desirable and contemplated herein to avoid film ruptures.

The vacuum chamber may be a part of an EUV scanner. It may have a direct connection with an EUV scanner as a part, an accessory, or an attachment of an EUV manufacturing assembly line. It may also be stand-alone for performing such annealing treatment near a scanner or remotely.

Annealing process may start with a nanofiber structure being mounted on a frame and then placed directly in an annealing chamber or a container. This chamber is pumped down to or near a vacuum at a level of about 10-4 torr or less. The chamber is then heated to a predetermined temperature. At this point, pellicles are placed in the chamber for a selected duration. Pellicles may be placed in the chamber before the heating is initiated. After the chamber returns to room temperature and atmospheric pressure with or without a cooling gas, such as argon, the process is complete, and pellicles can be stored in ambient conditions, in a vacuum, in inert gas, or a combination thereof to avoid contamination, exposure to atmospheric air other gases for possible oxidation, or damage.

The term annealing may include further aspects and broader interpretations in various technical fields and industries applicable to or related to the current disclosure. One or more present innovative contributions herein arise for the material science and semiconductor fields.

### Film Formation and Thermal Annealing

An ultra-thin and ultra-low density CNT pellicle film may be produced, followed by a thermal annealing process in accordance with exemplary embodiments of the current disclosure.

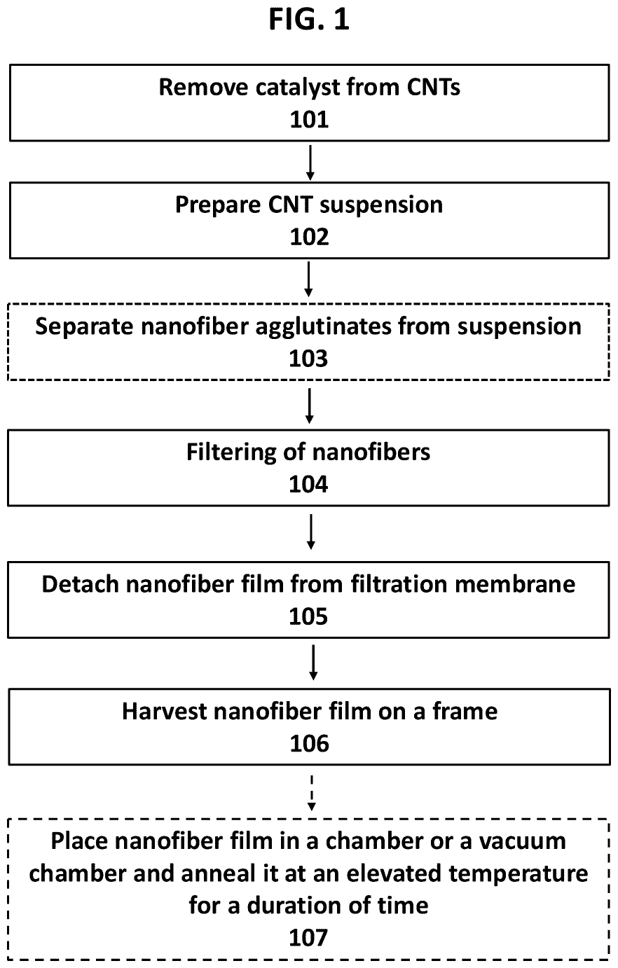

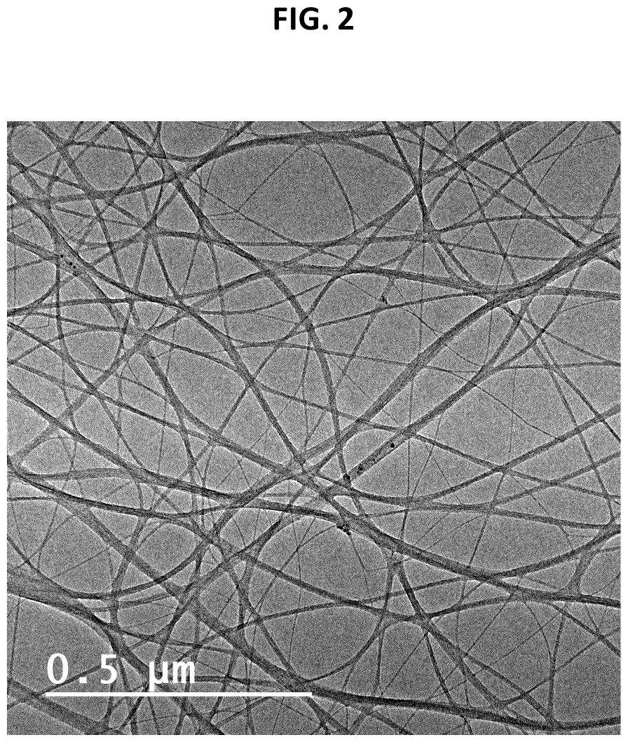

FIG. 1 illustrates a filtration method for forming a pellicle film, as shown in FIG. 2, followed by a subsequent annealing treatment in accordance with an exemplary embodiment.

Another embodiment of this disclosure may further include any pellicle films produced, to be produced, processed, or to be processed by all means prior to an annealing treatment. Furthermore, another embodiment of the present disclosure includes any other pellicle films with various CNT surface modifications, including but not limited to coating or other means of one or more metal elements, metal oxides, CNT surface modifiers, or a combination thereof.

As illustrated in FIG. 1, a free-standing carbon nanotube-based pellicle film may be produced via a filtration-based method. In Operation 101, catalysts are removed from carbon nanotubes (CNTs) that are to be used to form a water-based suspension. In an example, prior to dispersion into a suspension, the CNTs may be chemically purified to reduce a concentration of catalyst particles to less than 1% or preferably less than 0.5% wt. as measured by thermogravimetric analysis. Removal of the catalysts is not limited to any particular process or procedure, such that any suitable process may be utilized to achieve a desirable result.

In Operation 102, a water-based suspension is prepared using the purified CNTs, such that the purified CNTs are evenly dispersed in the water-based suspension. When preparing one or more CNT suspensions, carbon nanotube material can be mixed with a selected solvent to distribute nanotubes uniformly in a final solution as a suspension. Mixing can include mechanical mixing (e.g., using a magnetic stir bar and stirring plate), ultrasonic agitation (e.g., using an immersion ultrasonic probe), or other methods. In some examples, the solvent can be a protic or aprotic polar solvent, such as water, isopropyl alcohol (IPA), and aqueous alcohol mixtures, e.g., 60%, 70%, 80%, 90%, 95% IPA, N-Methyl-2-pyrrolidone (NMP), dimethyl sulfide (DMS), and combinations thereof. In another example, a surfactant can also be included to aid the uniform dispersion of carbon nanofibers in the solvent. Examples of surfactants include, but are not limited to, anionic surfactants.

Carbon nanofiber films are generally formed from one of MWCNTs, DWCNTs, or SWCNTs. A carbon nanofiber film may also include a mixture of different types of CNTs (i.e., SWCNTs, DWCNTs, and/or MWCNTs) with a variable ratio between the different types of CNTs. Other types of CNTs may also be used to produce CNT films by filtration and other known and contemplated methods.

Each of these three different types of common carbon nanotubes (e.g., MWCNT, DWCNT, and SWCNT) has different properties. In one example, single-wall carbon nanotubes can be more conveniently dispersed in a solvent (i.e., with the majority of nanotubes suspended individually and less adsorbed onto other nanotubes) for subsequent formation into a sheet of randomly oriented carbon nanotubes. This ability of individual nanotubes to be uniformly dispersed in a solvent can, in turn, produce a more planarly uniform nanotube film formed by removing the solvent from the suspended nanofibers. This physical uniformity can also improve the uniformity of other properties across the film (e.g., transparency and scattering to irradiation, mechanical strength upon pressure changes, and lifetime/durability test).

In an example, the water-based CNT suspension in Operation 102 may have at least above 85% purity of SWCNTs. The remaining may be a mixture of DWCNTs, MWCNTs and/or a catalyst. In other examples, a dispersed CNT suspension with various ratios of different types of CNTs may be prepared, such as about 20%/75% DWCNTs/SWCNTs, about 50%/45% DWCNTs/SWCNTs, about 70%/20% DWCNTs/SWCNTs, with MWCNTs accounted for the remaining. A mixture of 10% or more MWCNT and a blended DWCNT and SWCNT at various DWCNT/SWCNT percentage ratios may be prepared and subjected to the same filtration process of forming nanofiber structures. In an example, anionic surfactants may be utilized as the dispersants in the suspension to enhance the uniform dispersion of different types of CNT mixtures.

In Operation 103, the CNT suspension is then further purified to remove the aggregated or agglutinated CNTs from the initial mixture. In an example, different forms of CNTs, undispersed or aggregated vs. fully dispersed, may be separated from the suspension via centrifugation. Centrifugation of surfactant-suspended carbon nanotubes may aid in decreasing the turbidity of the suspension solution and ensuring a full dispersion of the carbon nanotubes in the final suspension solution before going into the next filtration step. However, aspects of the disclosure are not limited thereto, such that other separation methods or processes may be utilized. According to exemplary aspects, Operation 103 may be optionally performed or performed as a necessary step in the formation of the pellicle film.

In Operation 104, any CNT suspension, preferably the CNT supernatant after a separation procedure from Operation 103, is then filtered through a filtration membrane to form a CNT web, a continuous sheet of film of intersecting CNTs.

In an example, one technique for making the CNT film uses water or other fluids to deposit nanotubes in a random pattern on a filter, often a flat filtration membrane. The evenly dispersed CNT-containing mixture is allowed to pass or is forced to pass through the filter, leaving a nanofiber structural layer on the surface of the filter. The size and shape of the resulting films are determined by the size and shape of the desired filtration area of the filter, while the thickness and density of the films are determined by the quantity of nanofiber material applied during the process and the permeability of the filtration membrane to each ingredient of the input material, as the non-permeable ingredient is captured on the surface of the filter. If the concentration of nanofibers dispersed in the flow-through filtration fluid is known, the mass of nanofibers deposited onto the filter can be determined from the amount of such fluid that passes through the filter, and the film's areal density is determined by the nanofiber mass divided by the total filtration area. The selected filter is generally not permeable to any CNTs.

The filtration-formed CNT film may be of a combination of SWCNT, DWCNT, and/or MWCNT in differing compositions. Carbon nanofibers may become intersected randomly to form an interconnected network structure in a planar orientation to form a thin CNT film.

In Operation 105, the resulting CNT film is then separated from the filtration membrane, starting from a first edge of the CNT film toward a second edge, insignificantly overlapping with the first edge. When detached fully from the filtration membrane, the nanofiber film is ready for the next Operation 106.

In Operation 106, the detached CNT film is then harvested using a frame, sometimes referred to as a harvesting frame or a harvester frame, and then directly transferred and mounted onto virtually any solid substrate, such as a pellicle border with a defined aperture. The CNT film may be mounted to the pellicle border and cover the aperture to form a pellicle. The transferred film mounted on any frame, e.g., a metal frame, silicon frame, or a pellicle border, with an opening of as small as 5 mm×5 mm may be useful. A much larger size film, 110 mm×140 mm or greater, is in high demand, serving as a full-size pellicle film for an actual EUV scanner. CNT film characterization, such as an optical light transmittance and/or transmittance uniformity test, EUV transmittance and/or transmittance uniformity test, mechanical strength, deflection test, permeability test, deflection at a constant pressure or during pumping down conditions, lifetime test, particle test, may be performed. A full-size pellicle for EUV lithography scanning may require an ultra-thin, free-standing film generally larger than 110 mm×140 mm, based on current industry standards. A full-size pellicle may be referred to as a full-field pellicle.

A pellicle frame referred to herein may tolerate high-temperature treatments to sustain high-temperature annealing. Furthermore, it may have a low thermal expansion coefficient to avoid stretching or cause stretching of the nanofiber films mounted on itself. An exemplary frame material can be selected from silicon dioxide, commonly known as quartz, silicon carbide, etc.

In the optional Operation 107, a CNT film on a frame, pellicle border, or intermediate transferring frame, receives a thermal annealing treatment. A thermal annealing treatment is conducted by placing the CNT film in a closed chamber or a vacuum chamber at a predetermined elevated temperature for a specific duration. However, aspects of the present disclosure are not limited thereto, such that various thermal annealing treatment may be conducted at different temperatures, for different periods of time (duration), and by different thermal energy sources, e.g., different electromagnetic wavelengths or wavelength ranges.

In an example, the thermal annealing treatment may be conducted at a target temperature of about 600° C. and above, 700° C. and above, 800° C. and above, 900° C. and above, and less than about 3,000° C., 2,500° C., 2,000° C., or 1,500° C. The actual annealing temperature preferably stays constant, but it may fluctuate in a temperature range of 2-10% above and below the predetermined target temperature measured inside an annealing chamber or close to an annealing target, i.e., a pellicle film. For a target temperature of 600° C., the actual temperature may be measured at 540° C. to 660° C.

Also, in another example, the thermal annealing treatment may be conducted between 1 second to 60 minutes at a target temperature or temperature range. Preferred treatment duration may be between 10 minutes and 30 minutes.

In another example, annealing treatment may be performed in a chamber with an annealing chamber pressure at atmospheric pressure, in a vacuum, or between both. The annealing treatment chamber generally supports the distribution of thermal energy, preferably an even distribution throughout the entire chamber. Thermal energy may be directed toward a target or targets, such as one or more CNT films. It may also diffuse within the chamber, immerse one or more films, and treat the entire set of pellicle films evenly with less variation. Any annealing variation, such as uneven energy deposited on a film, or uneven energy received at the film, may cause, for example, film wrinkles, focal film thickening or thinning, premature film breakage, etc. Any of these events or changes can alter film light transmission rates, worsen transmission variation, weaken film mechanical strength, and shorten film lifetime.

In another example, annealing treatment may be performed by electromagnetic radiation. A selected electromagnetic wave(s), ranging from 1 nm to 1 mm in a single wavelength or a mixed two or more overlapping and/or non-overlapping wavelengths, targets at least one portion of a pellicle film or preferably the entire pellicle film for a pre-determined duration from 0.1 milliseconds to 1 second.

### EUV Transmission and EUV Transmission Reduction

It is required for an extreme ultraviolet (EUV) pellicle to have a high EUV transmission rate. This is especially important for current EUV photolithography and future high-power EUV photolithography. A typical EUV transmission rate, often measured at about 13.5 nm wavelength, is generally 75% and above, 80% and above, 88% and above, 92% and above, or preferably 95% and above, and up to 99%. The EUV pellicle film may be further annealed to enhance EUV transmission rate. In an example, a CNT film produced from Operation 101 to Operation 107, may yield a transmission rate at EUV 13.5 nm wavelength of about 93.05%. However, storage conditions for nanofiber EUV pellicle film and CNT EUV pellicle film are not clearly understood. The above-mentioned CNT pellicle film, having an EUV transmission rate of 93.05%, was remeasured for its EUV transmission rate after storing for one month in a stainless steel container (about 100 cubic inches with an internal chamber of 15 cu. inches). Another CNT pellicle film from the same sample preparation batch (sibling sample) was stored in an acrylic container (3.5″×3.5″×0.5″ (length×width×height) with 1/16″-thick container material) for one month, and the film's EUV transmission rate was measured. Both samples and their containers were stored in ambient conditions, i.e., normal atmospheric pressure, same room temperature, and same humidity. Both containers were filled with room air. The results are summarized in Table 1 below.

TABLE 1

| | EUV Trans- | EUV Trans- | |
|---|---|---|---|
| Material for | mission rate, | mission rate, | EUV Trans- |
| Storage | 1-day after | 1-month storage | mission |
| Container | annealing (%) | after annealing (%) | Reduction (%) |
| Stainless Steel | 93.05 | 92.48 | 0.57 |
| Acrylic Plastic | 93.05 | 92.03 | 1.02 |

Table 1 shows the EUV transmission rate of an annealed CNT film changes over time based on the pellicle film storage conditions. The EUV transmission rate reduction for samples stored in the insulated acrylic plastic container drops twice as fast as the EUV transmission reduction for the sample stored in the stainless steel container. Both insulation containers are not vacuumed sealed, not inert gas filled, and are exposed to a similar amount of ambient air within the containers.

Acrylic is a transparent plastic commonly used as a storage container material due to its excellence in optical clarity and transparency, resistance to temperature variation, and resistance to various chemicals. However, it also has a high outgassing rate. The outgassed volatile organic compounds from the acrylic container, although having a much smaller container vs. the stainless steel container, double the EUV transmission rate reduction when comparing these two storage container materials. Other low-outgassing plastics, e.g., polyvinylidene fluoride (PVDF), polyether ether ketone (PEEK), polytetrafluoroethylene (PTFE or Teflon®), polyimide, ethylene-chlorotrifluoroethylene (ECTFE), polycarbonate, may be a better choice for EUV pellicle container material. Long-term storage of pellicles in any synthetic plastic containers may still have higher than usual adverse impacts on ultra-thin CNT pellicles and pellicle film properties and should be carefully evaluated. Pre-purging of a pellicle film storage or shipping container, including the container material itself and/or the interior container storage space with a selected inert gas, including but not limited to nitrogen and argon, could be a preventative option. The container material pre-purged with the selected inert gas may outgas such inert gas when vacuum-sealed.

### FTIR Spectroscopy Measurement

Fourier-transform infrared spectroscopy (FTIR spectroscopy) measures how much light a target sample, such as a liquid, a gas, or a solid, absorbs at each wavelength over the infrared spectrum. A sample material absorbs a portion of infrared radiation due to its chemical properties and compositions, while other infrared radiation passes through and may reach detectors for recording. A computer analyses the recorded raw data, called an interferogram, and arranges and displays corresponding light absorption or transmittance at each wavelength in a diagram. For a given sample material, it has its representative data set and a computer-generated curve in a graph, like a fingerprint of the tested material. When the same material is modified, its light absorption characteristics may change due to alterations in its structure, chemical compositions, chemical residues, and the resulting molecular vibration patterns. These changes will draw up a new data set or new curve.

As most materials include more than one chemical ingredient, contaminants, or outgassing substances, FTIR spectroscopy is likely to represent the absorption characteristics of a material mixture and presents a more complex graph or graph pattern. A specific range of spectroscopy wavelength may be a typical, meaningful, and/or sufficient representation to indicate the changes within a given tested material.

Comparing the data collected before and after annealing of a sample material may reveal changes accumulated within the same material. Similar comparison results often correlate with different measurements from the same sample material type treated in the same way or undergoing similar changes of the sample material.

When studied in addition to EUV transmission measurements, differences observed by FTIR may represent or correlate to the same modifications inside a nanofiber pellicle film.

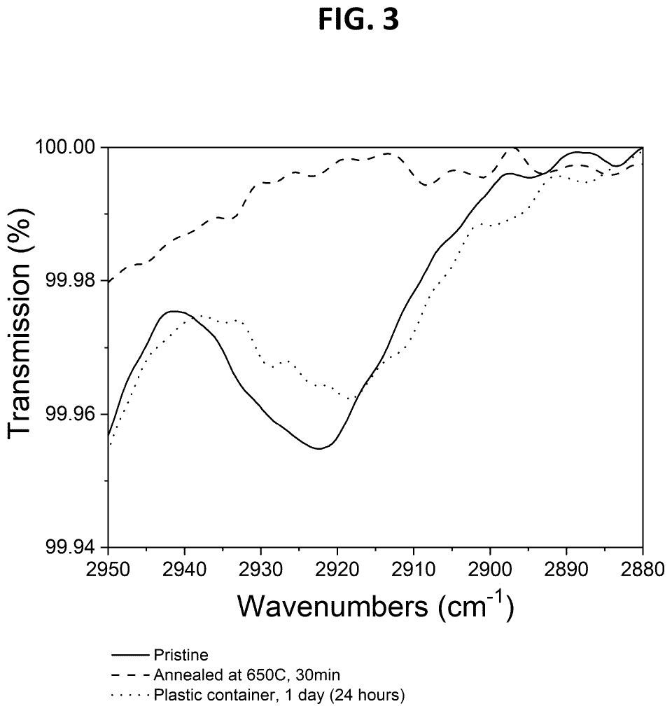

In an experiment, a CNT pellicle film was first annealed at 650° C. for 30 min and then stored in an acrylic plastic container (3.5″×3.5″×0.5″ with 1/16″-thick wall) with a silicon rubber-based material, such as a silicon rubber gasket or silicon rubber spacer strip (3.0″×0.25″×0.25″), for 24 hours. FTIR measurements of the CNT pellicle film were performed before annealing (often referred to as pristine CNT pellicle film), after annealing, and 24 hours after storing in the acrylic plastic container with silicone rubber material. The results (from wavenumber 2950 (cm⁻¹) and 2880 (cm⁻¹)) are plotted in FIG. 3, showing significant changes among these measurement results for wavenumbers between 2940 (cm⁻¹) and 2900 (cm⁻¹). Before annealing, the graph of the pristine CNT pellicle film (solid curve) has a deep “V” shape between 2940 (cm⁻¹) and 2900 (cm⁻¹). After annealing, the graphed line was flattened (the annealed CNT pellicle film shown in the dashed curve) but returned to a curvature very close to the original graph after storing it in the acrylic plastic container with silicone rubber (the annealed CNT pellicle film stored in the acrylic plastic container for 24 hours and measured next day in the dotted curve). These changes indicate an initial loss of certain substances on the surface of CNTs due to the measured gain of infrared transmission and then a regain of the loss of a substance shown in infrared transmission reduction. Typical chemical substances represented by the indicated wavenumber range in literature may be aliphatic hydrocarbons. Also, these FTIR measurement changes correspond to the previously observed changes from direct EUV transmission measurement and changes in EUV transmission, as shown above, and other data not included herein.

The silicone rubber is reported to continue to outgas at a very low level. It is also known for its potential to outgas at high temperatures and low pressures. Although the outgassed amount may be negligible for non-EUV lithography applications, its effects on ultra-thin CNT pellicle films may be significant. CNT pellicle films could adsorb a tiny amount of outgas and change their EUV transmission rates.

In summary, acrylic plastic and/or rubbery material affects EUV transmission rates of ultra-thin CNT pellicle films. More specifically, the studied material may reduce EUV transmission rates of thin CNT pellicle films.

Other common storage container material includes, but not limited to, polycarbonate plastic, polypropylene plastic, or any other synthetic material which may release or outgas a trace amount of the original starting ingredients (monomer or polymer), VOC, and/or catalysts.

According to another aspect of the present disclosure, exposure to the above-described material for CNT EUV pellicle film storage container and transportation container may affect not only EUV transmission rate but also EUV scattering, EUV pellicle film deflection, EUV pellicle film tensile strength, or a combination thereof. As CNT EUV pellicle films are typically in a few to a few-tens nanometer thickness range, adsorption of aliphatic carbons could eventually add weight to the ultra-light film, causing film sagging and tensile strength reduction.

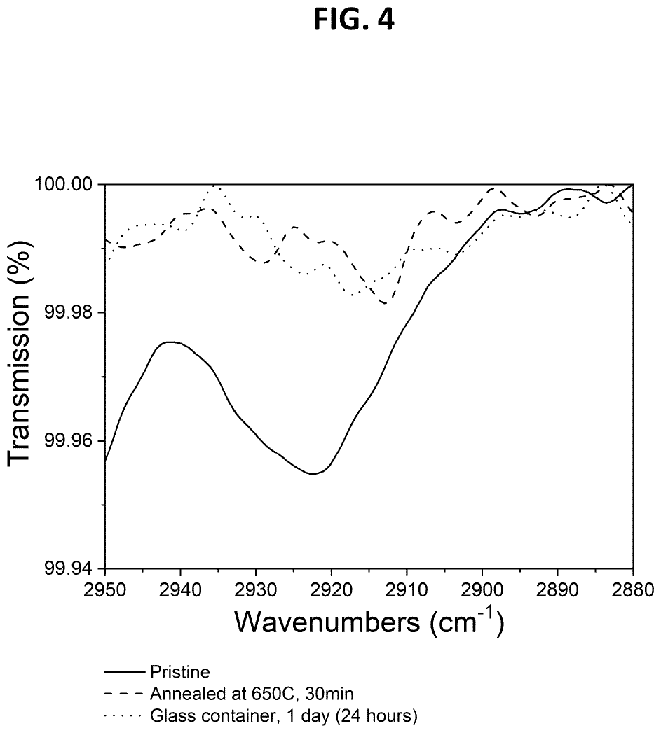

In another experiment, a CNT pellicle film was annealed first at 650° C. for 30 min and then stored in a glass container for 24 hours in atmospheric pressure, humidity, and room air. FTIR measurements of this CNT pellicle film were performed before annealing, after annealing, and 24 hours after storing it in a glass container. The results are plotted in FIG. 4, demonstrating a different pattern compared to FIG. 3. After annealing treatment, the graphed line (dashed curve-annealed CNT pellicle film) was also flattened, as expected, but did not return a curvature close to the original graph, a solid curve based on measurement before annealing. It retained a similar baseline (dotted curve-measurement after storing the annealed CNT pellicle film in a glass container) following the results measured right after annealing. This set of FIG. 4 data indicates glass has little or no effect on EUV transmission of an ultra-thin CNT pellicle film, at least for the tested period.

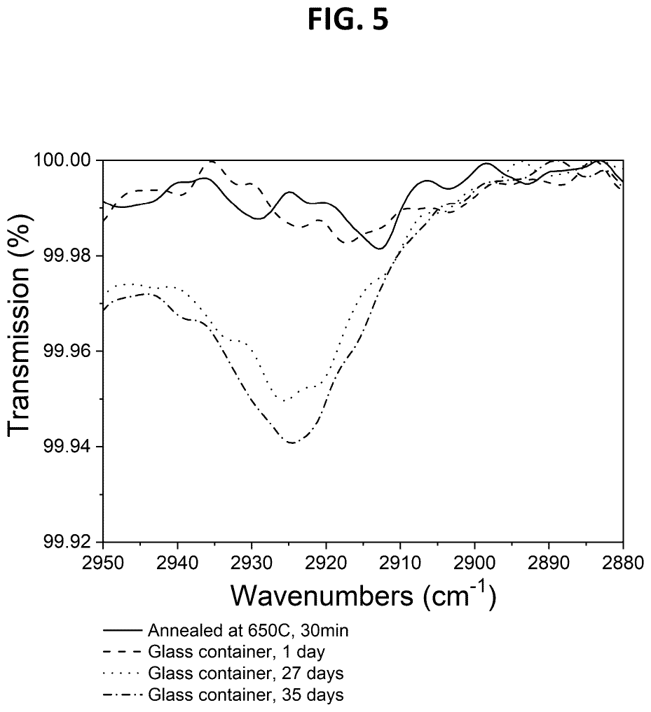

Yet in a study of testing extended exposure of storage container material, a CNT pellicle film was annealed at 650° C. for 30 min first and then stored in a glass container for up to 35 days under ambient conditions with room air. FTIR measurements of this CNT pellicle film were performed before the annealing and 24 hours (1 day), 27 days, and 35 days after storing it in the glass container. The results were plotted in FIG. 5. After the annealing, the graphed line was flattened with a disappearance of the “V” shape (solid curve), which is similar to the corresponding changes and curves in both FIGS. 3 and 4. After 24-hour storage in the glass container, the FTIR measurements (dashed curve) did not show significant changes. The sample was remeasured 27 and 35 days later. The graph representing the measurements taken 27 days after the annealing (dotted curve) displayed a curvature mostly between the data sets of the unannealed samples (not shown) and the annealed sample 24 hours after annealing, i.e., the deep “V” characteristics and infrared transmission reduction in the corresponding wavelength range. The graph representing the measurements taken 35 days after the annealing (dash-dotted curve) shows a deeper “V” curvature and further infrared transmission reduction. The result again indicates a reacquisition of aliphatic hydrocarbons on the surface of CNTs at a very slow pace for a CNT pellicle film stored in a glass container compared to acrylic container storage. Both will eventually affect EUV transmission of CNT EUV pellicles.

The embodiments of this disclosure further demonstrate the need and/or necessity of storing nanofiber EUV pellicle or pellicle film in a vacuum condition, in room air or gas-purged-environment, or in an inert gas-filled container with carefully selected storage and shipping container materials.

Preferred EUV pellicle or pellicle film container material may include, but not limited to, a metal, stainless steel, glass, borosilicate glass, glass-ceramic, or quartz. The illustrations of the embodiments described herein are intended to provide a general understanding of the various embodiments. The illustrations are not intended to serve as a complete description of all of the elements and features of products and methods that form the products or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The subject matter discussed herein is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A storage device comprising:
a material, wherein
the material maintains one or more properties of an extreme ultraviolet (EUV) lithography pellicle, and
the one or more properties are selected from EUV transmission rate, EUV transmission variation, EUV scattering, EUV pellicle film deflection, EUV pellicle film tensile strength, or a combination thereof.

2. The storage device of claim 1, wherein the material outgases to maintain the one or more properties of the EUV lithography pellicle.

3. The storage device of claim 1, wherein the material is stainless steel.

4. The storage device of claim 1, wherein the material is selected from glass or borosilicate glass.

5. The storage device of claim 1, wherein the material is selected from glass-ceramic or quartz.

6. The storage device of claim 1, wherein the storage device is vacuum-sealed.

7. The storage device of claim 1, wherein the storage device is filled with an inert gas.

8. The storage device of claim 1, wherein the material is pre-purged with an inert gas.

9. A method of storing an extreme ultraviolet (EUV) lithography pellicle, the method comprising:
preparing an EUV lithography pellicle; and
placing the EUV lithography pellicle in a container,
wherein
the container comprises at least a material, and
the material maintains EUV lithography pellicle one or more properties selected from EUV transmission rate, EUV transmission variation, EUV scattering, deflection of EUV lithography pellicle film, tensile strength of EUV lithography pellicle film, or a combination thereof.

10. The method of claim 9, wherein
the material is selected from stainless steel, glass, borosilicate glass, glass-ceramic, or quartz.

11. The method of claim 9, further comprising:
maintaining a vacuum pressure within the container.

12. The method of claim 9, further comprising:
filling the container with an inert gas.

13. The method of claim 9, further comprising:
purging the material included in the container with an inert gas.
